(19) United States
(12) Patent Application Publication
(10) Pub. No.: US 2025/0091357 A1
(43) Pub. Date: Mar. 20, 2025

(54) APPARATUS FOR MANUFACTURING DISPLAY DEVICE

(71) Applicant: Samsung Display Co., LTD., Yongin-si (KR)

(72) Inventors: Jungwoong BYUN, Yongin-si (KR); Wonjoon CHOI, Yongin-si (KR)

(21) Appl. No.: 18/673,607

(22) Filed: May 24, 2024

(30) Foreign Application Priority Data
Sep. 15, 2023 (KR) 10-2023-0123317

(51) Int. Cl. B41J 2/175; B41J 2/185; B41J 3/407

(52) U.S. Cl. CPC B41J 2/17596; B41J 2/185; B41J 3/407

(57) ABSTRACT

An apparatus for manufacturing a display device includes: a stage on which a display substrate is arranged; an ink discharge module which discharges ink onto the display substrate; and an ink supply module which supplies ink to the ink discharge module. The ink supply module includes: a storage portion in which ink is stored; a first flow path connecting the storage portion to the ink discharge module in a way such that ink stored in the storage portion flows into the ink discharge module; and a second flow path connecting the storage portion to the ink discharge module in a way such that ink supplied to the ink discharge module flows into the storage portion.

This application claims priority to Korean Patent Application No. 10-2023-0123317, filed on Sep. 15, 2023, and all the benefits accruing therefrom under 35 U.S.C. § 119, the content of which in its entirety is herein incorporated by reference.

### BACKGROUND

### 1. Field

One or more embodiments relate to an apparatus, and more particularly, to an apparatus for manufacturing a display device.

### 2. Description of the Related Art

Mobility-based electronic devices have been widely used. Recently, tablet personal computers (PCs), in addition to small electronic devices such as mobile phones, have been widely used as mobile electronic devices.

In order to support various functions, such mobile electronic devices typically include a display device to provide visual information such as an image or a video to a user. Recently, as the sizes of other components for driving a display device have decreased, the area occupied by a display device in electronic devices has gradually increased, and a structure that may be bent by a certain angle from a flat state has been developed.

### SUMMARY

One or more embodiments include an ink supply module in which, when ink flows to an ink discharge module from a storage portion, the ink flows at a high flow rate until a point adjacent to the ink discharge module and the flow rate of the ink is reduced immediately before the ink is supplied to the ink discharge module.

According to one or more embodiments, an apparatus for manufacturing a display device, includes a stage on which a display substrate is arranged, an ink discharge module which discharges ink onto the display substrate, and an ink supply module which supplies ink to the ink discharge module, where the ink supply module includes a storage portion in which ink is stored, a first flow path connecting the storage portion to the ink discharge module in a way such that ink stored in the storage portion flow into the ink discharge module, and a second flow path connecting the storage portion to the ink discharge module in a way such that ink supplied to the ink discharge module flows into the storage portion, and the first flow path includes a supply flow path having a first end connected to the storage portion and a second end connected to the ink discharge module in a way such that ink introduced from the storage portion is supplied to the ink discharge module, and a recovery flow path having a first end connected to the supply flow path and a second end connected to the storage portion in a way such that ink introduced into the supply flow path is recovered into the storage portion

In an embodiment, the ink discharge module may include a plurality of head portions configured to spray ink, where the number of the plurality of head portions is 2ⁿ⁺¹ (where n is a natural number), and the supply flow path may include a first supply flow path through which ink is introduced from the storage portion, a second supply flow path branched into 2 parts from the first supply flow path, and a third supply flow path connecting the second supply flow path to the plurality of head portions.

In an embodiment, shapes of cross-sections of the second supply flow path branched into 2 parts may be identical to each other.

In an embodiment, a sum of areas of cross-sections of the second supply flow path branched into 2 parts may be identical to an area of a cross-section of the first supply flow path.

In an embodiment, the first supply flow path may include a first first supply flow path portion including a flexible material and connected to the storage portion, and a second first supply flow path including a solid material and connecting the first first supply flow path to the second supply flow path.

In an embodiment, the second first supply flow path portion may have a straight line shape.

In an embodiment, each part of the second supply flow paths branched into 2 parts may include a first second supply flow path portion connected to the first supply flow path and having a curved shape, and a second second supply flow path portion connecting the first second supply flow path portion to the third supply flow path and having a straight line shape.

In an embodiment, the ink supply module may further include a first pump disposed on the first supply flow path in a way such that ink introduced into the supply flow path flows onto the ink discharge module.

In an embodiment, the recovery flow path may connect the storage portion to the third supply flow path.

In an embodiment, the recovery flow path may include a first recovery flow path connected to the storage portion, a second recovery flow path branched into 2 parts from the first recovery flow path, and a third recovery flow path connecting the second recovery flow path to the third supply flow path.

In an embodiment, shapes of cross-sections of the second recovery flow path branched into 2 parts may be identical to each other.

In an embodiment, a sum of areas of cross-sections of the second recovery flow path branched into 2 parts may be identical to an area of a cross-section of the first recovery flow path.

In an embodiment, the first recovery flow path may include a first first recovery flow path portion including a flexible material and connected to the storage portion, and a second first recovery flow path including a solid material and connecting the first first recovery flow path portion to the second recovery flow path.

In an embodiment, the second first recovery flow path portion may have a straight line shape.

In an embodiment, each part of the second recovery flow paths branched into 2 parts may include a first second recovery flow path portion connected to the first recovery flow path and having a curved shape, and a second second recovery flow path portion connecting the first second recovery flow path portion to the third recovery flow path and having a straight line shape.

In an embodiment, the ink supply module may further include a second pump arranged on the first recovery flow path in a way such that ink introduced into the recovery flow path flows into the storage portion.

In an embodiment, the second flow path may include a first second flow path connected to the storage portion, a second second flow path branched into 2 parts from the first second flow path, and a third second flow path connecting the second second flow path to the plurality of head portions.

In an embodiment, shapes of cross-sections of the second second flow path branched into 2 parts may be identical to each other.

In an embodiment, a sum of areas of cross-sections of the second second flow path branched into 2 parts may be identical to an area of a cross-section of the first second flow path.

In an embodiment, the first second flow path may include a first sub flow path portion including a flexible material and a second sub flow path portion including a solid material and connecting the first sub flow path portion to the second second flow path portion.

Other features other than the above description will be clear from the details of the drawings, the claim of claims and the details of the invention.

### BRIEF DESCRIPTION OF THE DRAWINGS

The above and other features of certain embodiments of the disclosure will be more apparent from the following description taken in conjunction with the accompanying drawings, in which:

FIG. 1 is a perspective view schematically illustrating an apparatus for manufacturing a display device, according to an embodiment;

FIG. 2 is a perspective view schematically illustrating an ink supply module according to an embodiment;

FIG. 3 is a perspective view schematically illustrating a first flow path according to an embodiment;

FIG. 4 is a perspective view schematically illustrating a second flow path according to an embodiment;

FIG. 5 is a plan view schematically illustrating a display device according to an embodiment;

FIG. 6 is a cross-sectional view schematically illustrating a display device according to an embodiment; and

FIG. 7 is an equivalent circuit diagram of a pixel of a display panel according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

Since various modifications and various embodiments are possible, specific embodiments are illustrated in the drawings and described in detail in the detailed description. Effects and features of the disclosure, and a method of achieving them will be apparent with reference to embodiments described below in detail in conjunction with the drawings. However, the disclosure is not limited to the embodiments disclosed herein, but may be implemented in a variety of forms.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the following embodiments, when a portion such as a layer, a region, an element or the like is on other portions, this is not only when the portion is on other elements, but also when other elements are interposed therebetween.

In the drawings, for convenience of explanation, the sizes of elements may be exaggerated or reduced. For example, since the size and thickness of each component shown in the drawings are arbitrarily indicated for convenience of explanation, the present disclosure is not necessarily limited to the illustration.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In the following embodiments, the x-axis, the y-axis, and the z-axis are not limited to three axes on a Cartesian coordinate system, and may be interpreted in a broad sense including the same. For example, the x-axis, the y-axis, and the z-axis may be perpendicular to each other, but may refer to different directions that are not orthogonal to each other.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the present specification, in the case where some embodiments may be implemented in the present specification, a specific process order may be performed differently from the order described. For example, two processes described in succession may be substantially performed at the same time, or in an opposite order to an order to be described.

Hereinafter, embodiments will be described in detail with reference to the accompanying drawings, and the same or corresponding components are denoted by the same reference numerals, and the same reference numerals are assigned and any repetitive detailed description thereof will be omitted or simplified.

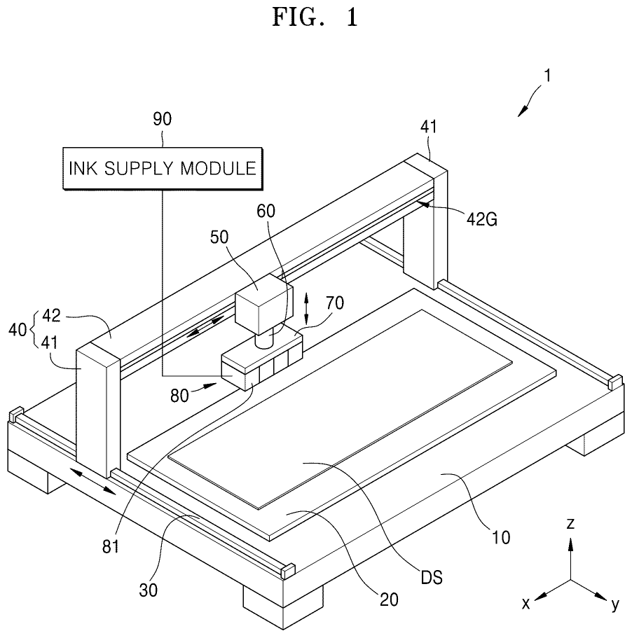

FIG. 1 is a perspective view schematically illustrating an apparatus 1 for manufacturing a display device according to an embodiment.

Referring to FIG. 1, an embodiment of the apparatus 1 for manufacturing the display device may include a support portion 10, a stage 20, a guide portion 30, a first moving portion 40, a second moving portion 50, a third moving portion 60, a connection frame 70, an ink discharge module 80, and an ink supply module 90.

The support portion 10 may support the stage 20, the guide portion 30, the first moving portion 40, the second moving portion 50, the third moving portion 60, the connection frame 70, and the ink discharge module 80. FIG. 1 illustrates an embodiment where the shape of the support portion 10 is a hexagonal shape. However, this is just an example, and the shape of the support portion 10 is not limited thereto.

The stage 20 may be arranged above the support portion 10. A display substrate DS may be arranged on the stage 20. The stage 20 may include an alignment mark for aligning a display substrate DS thereon. Here, the display substrate DS that is part of the display device being manufactured, may be an object to which ink is discharged by the ink discharge module 80. The stage 20 may constitute a work area of an inkjet printing process.

The guide portion 30 may be arranged above the support portion 10. In an embodiment, for example, two guide portions 30 may be provided and may be spaced apart from each other and arranged at opposing sides of the stage 20 therebetween. A length of the guide portion 30 may be greater than at least a length of a side of the display substrate DS. The guide portion 30 may guide the first moving portion 40 to make a linear motion in a longitudinal direction of the guide portion 30. In an embodiment, for example, the guide portion 30 may include a linear motion rail.

The first moving portion 40 may be arranged on the support portion 10 and make a linear reciprocation motion with respect to the stage 20. The first moving portion 40 may include a pillar member 41 and a horizontal member 42. FIG. 1 illustrates an embodiment where the pillar member 41 and the horizontal member 42 have a rectangular rod shape. However, the shapes of the pillar member 41 and the horizontal member 42 are not limited thereto.

The pillar member 41 may be connected to the guide portion 30. In an embodiment, for example, two pillar members 41 may be provided and may be spaced apart from each other and arranged at the opposing sides of the stage 20 therebetween. The pillar member 41 may move in the longitudinal direction of the guide member 30. The pillar member 41 may make a linear motion manually or make a linear motion automatically by including a motor cylinder or the like. In an embodiment, for example, the pillar member 41 may make a linear motion automatically by including a linear motion block that moves along the linear motion rail.

The horizontal member 42 may be fixed to the pillar member 41. The horizontal member 42 may be disposed between two pillar members 41. A horizontal groove 42G extending the longitudinal direction may be defined in the horizontal member 42. The horizontal groove 42G may be provided on one side of the horizontal member 42. The horizontal groove 42G may guide the second moving portion 50 to make a linear reciprocation motion in the longitudinal direction of the horizontal groove 42G.

The second moving portion 50 may be connected to the first moving portion 40 and make a linear reciprocation motion with respect to the first moving portion 40. In an embodiment, for example, at least part of the second moving portion 50 may be accommodated in the horizontal groove 42G of the horizontal member 42. The second moving portion 50 may move in the longitudinal direction of the horizontal groove 42G. In an embodiment, for example, the second moving portion 50 may include a linear motor or the like.

The third moving portion 60 may be connected to the second moving portion 50 and make a linear reciprocation motion with respect to the second moving portion 50. In an embodiment, for example, the third moving portion 60 may be arranged on a lower surface (e.g., a surface toward-z-axis direction) of the second moving portion 50. Here, the lower surface (e.g., a surface toward-z-axis direction) of the second moving portion 50 may be a surface thereof facing toward the stage 20. In an embodiment, for example, the third moving portion 60 may include a pneumatic cylinder and the like. The third moving portion 60 may be rotated around a rotation axis, and the third moving portion 60 may include an electric motor, a pneumatic motor or the like to rotate.

The connection frame 70 may be connected to the third moving portion 60. In an embodiment, for example, the connection frame 70 may be arranged on a lower surface (e.g., a surface toward-z-axis direction) of the third moving portion 60. Here, the lower surface (e.g., a surface toward-z-axis direction) of the third moving portion 60 may be a surface thereof facing toward the stage 20. The movement directions of the first moving portion 40, the second moving portion 50, and the third moving portion 60 may cross each other. In this structure, the connection frame 70 may be freely moved to a specified position in three dimensions.

The ink discharge module 80 may be connected to the connection frame 70. In an embodiment, for example, the ink discharge module 80 may be arranged on a lower surface (e.g., a surface toward-z-axis direction) of the connection frame 70. Here, the lower surface (e.g., a surface toward-z-axis direction) of the connection frame 70 may be a surface thereof facing toward the stage 20. In this structure, the ink discharge module 80 may be freely moved to a specified position in three dimensions. The ink discharge module 80 may discharge ink onto the display substrate DS. The ink discharge module 80 may include a plurality of head portions 81 for spraying ink. The plurality of head portions 81 may be arranged in a line. FIG. 1 illustrates an embodiment where four head portions 81 are provided. However, this is just an example, and the number of a plurality of head portions 81 is not limited thereto.

Ink may be attached to the display substrate DS to form part of layers of the display device. In an embodiment, ink may be a polymer or low molecular weight organic material that corresponds to a light-emitting layer of an organic light-emitting display device. In another embodiment, the ink may be liquid of red, green, and blue in which pigment particles are mixed with liquid crystal, orientation and solvent. In another embodiment, the ink may include a solution including inorganic particles such as quantum dot materials or the like.

The ink supply module 90 may supply ink to the ink discharge module 80. The ink supply module 90 may be connected to the ink discharge module 80 via one or more flow paths. In an embodiment, for example, the ink supply module 90 may be supported by the support portion 10. In an embodiment, for example, the ink supply module 90 may be fixed to at least one selected from the first moving portion 40, the second moving portion 50, the third moving portion 60, and the connection frame 70. This is just an example, and the arrangement of the ink supply module 90 is not limited thereto. In an embodiment, for example, the ink supply module 90 may be arranged outside the support portion 10 and may supply ink to the ink discharge module 80.

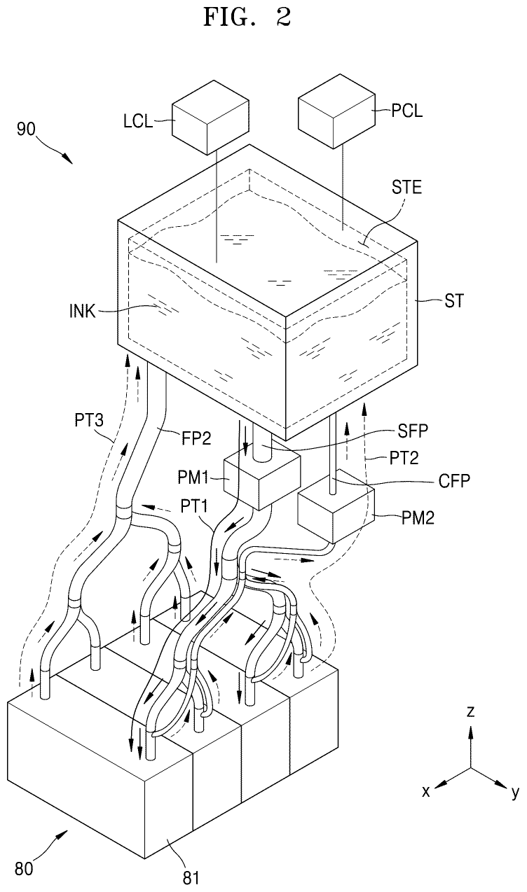

FIG. 2 is a perspective view schematically illustrating the ink supply module 90 according to an embodiment.

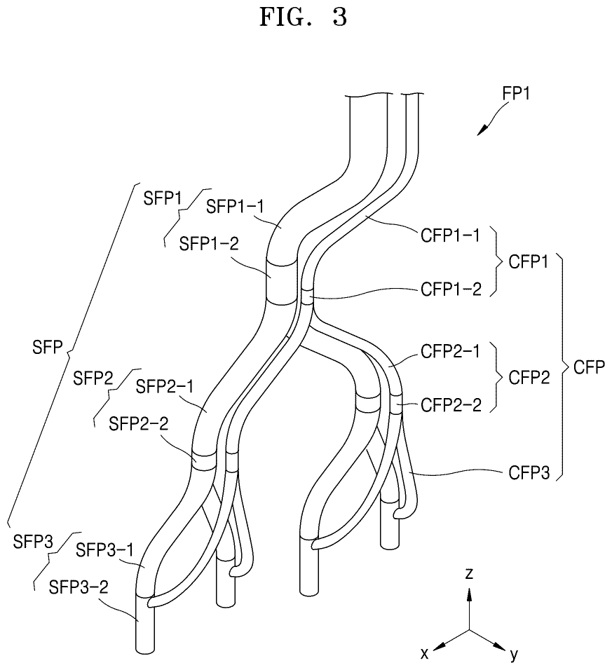

Referring to FIG. 2, in an embodiment, the ink supply module 90 may include a storage portion ST, a first flow path FP1 (shown in FIG. 3), a first pump PM1, a second pump PM2, a second flow path FP2, a liquid level control portion LCL, and a pressure control portion PCL.

The storage portion ST may store ink INK. The storage portion ST may provide a storage space STE, and the ink INK may be accommodated in the storage portion STE. The storage space STE may be sealed by the storage portion ST. FIG. 2 illustrates an embodiment where the storage portion ST and the storage space STE have a hexagonal shape. However, this is just an example, and the shapes of the storage portion ST and the storage space STE are not limited thereto.

The first flow path FP1 may connect the storage portion ST to the ink discharge module 80 so that the ink INK stored in the storage portion ST may flow to the ink discharge module 80. The first flow path FP1 may include a supply flow path SFP and a recovery flow path CFP.

One side (or a first end) of the supply flow path SFP may be connected to the storage portion ST, and the other side (or a second end) of the supply flow path SFP may be connected to the ink discharge module 80. The supply flow path SFP may communicate with the storage space STE of the storage portion ST and may be connected to each of the plurality of head portions 81. Thus, the ink INK flowing onto the supply flow path SFP from the storage portion ST may be supplied to the ink discharge module 80.

One side (or a first end) of the recovery flow path CFP may be connected to the supply flow path SFP, and the other side (or a second end) of the recovery flow path CFP may be connected to the storage portion ST. The recovery flow path CFP may communicate with each of the storage space STE and the supply flow path SFP of the storage portion ST. Thus, part of the ink INK flowing onto the supply flow path SFP may be recovered to the storage portion ST.

The first pump PM1 may be arranged on the supply flow path SFP and may control the flow of the ink INK flowing onto the supply flow path SFP. The ink INK introduced into the supply flow path SFP by the first pump PM1 may flow toward the ink discharge module 80 from the storage portion ST.

The second pump PM2 may be arranged on the recovery flow path CFP and may control the flow of the ink INK introduced into the recovery flow path CFP. The ink INK introduced to the recovery flow path CFP by the second pump PM2 may flow toward the storage portion ST from the ink discharge module 80.

In such an embodiment, the ink INK introduced into the supply flow path SFP from the storage portion ST may flow along a first path PT1 toward the ink discharge module 80. Also, the ink INK introduced to the recovery flow path CFP from the supply flow path SFP may flow along a second path PT2 toward the storage portion ST. In addition to the ink INK that flows along the second path PT2 among the ink INK flowing along the first path PT1, the remaining ink INK may be finally supplied to the ink discharge module 80.

The flow rate of the ink INK supplied to the ink discharge module 80 may be a flow rate that is obtained by excluding the flow rate of the ink INK that flows along the second path PT2 from the flow rate of the ink INK flowing along the first path PT1. That is, a flow rate that is obtained by adding the flow rate of the ink INK supplied to the ink discharge module 80 to the flow rate of the ink INK flowing along the second path PT2 may be a flow rate of the ink INK that flows along the first path PT1.

Thus, in the process in which the ink INK introduced into the supply flow path SFP flows along the first path PT1 and is supplied to the ink discharge module 80, the flow rate of the ink INK may be reduced at a boundary of a connection point with the recovery flow path CFP. The ink INK introduced into the supply flow path SFP may flow at a relatively high flow rate before the connection point with the recovery flow path CFP. Thus, a phenomenon that the ink INK is precipitated or blocks the flow path while the ink INK flows, may be reduced.

In such an embodiment, the ink INK introduced into the supply flow path SFP may flow at a relatively low flow rate when passing the connection point with the recovery flow path CFP. Thus, a target ink INK inflow flow rate desired in the ink discharge module 80 may be satisfied. In addition, the effects of a pulse phenomenon on the ink discharge module 80 generated by the first pump PM1 and the second pump PM2 may be substantially reduced, such that the ink discharge module 80 may discharge the ink INK stably.

In an embodiment, the ink INK introduced into the supply flow path SFP may flow at a high flow rate until a position adjacent to the ink discharge module 80, and then the flow rate of the ink INK may be reduced immediately before the ink INK is supplied to the ink discharge module 80. Thus, a phenomenon that the ink INK introduced into the supply flow path SFP may be precipitated or may block the flow path while flowing along the first path PT1, may be reduced and simultaneously, the target ink INK inflow flow rate required by the ink discharge module 80 may be satisfied. In this case, a pumping degree of the first pump PM1 and the second pump PM2 may be controlled in consideration of the flow rate of the ink INK flowing along the supply flow path SFP and the recovery flow path CFP.

The second flow path FP2 may connect the storage portion ST to the ink discharge module 80 so that part of the ink INK supplied to the ink discharge module 80 may flow into the storage portion ST. The ink INK introduced into the second flow path FP2 may flow along a third path PT3 toward the storage portion ST. One side (or a first end) of the second flow path FP2 may be connected to the ink discharge module 80, and the other side (or a second end) of the second flow path FP2 may be connected to the storage portion ST. The second flow path FP2 may communicate with the storage space STE of the storage portion ST and may be connected to each of the plurality of head portions 81. Part of the ink INK introduced into the ink discharge module 80 may be sprayed by a plurality of spraying portions, and the other part of the ink INK may be introduced into the second flow path FP2 and may flow into the storage portion ST.

The liquid level control portion LCL may control the level of the ink INK arranged in the storage space STE of the storage portion ST. An additional liquid level sensor may be arranged in the storage portion ST, and the liquid level control portion LCL may control the level of the ink INK based on the level sensed by the liquid level sensor. In an embodiment, for example, the liquid level control portion LCL may supply the ink INK into the storage portion ST so that the level of the ink INK arranged in the storage space STE may be constant.

The pressure control portion PCL may control the pressure of the storage space STE of the storage portion ST. in an embodiment, for example, the pressure control portion PCL may control the pressure so that a negative pressure may be formed in the storage space STE of the storage portion ST. A phenomenon that the ink INK unintentionally flows from the ink discharge module 80 to the outside due to a negative pressure formed in the storage space STE, may be reduced.

FIG. 3 is a perspective view schematically illustrating a first flow path FP1 according to an embodiment.

Referring to FIGS. 2 and 3, in an embodiment, the first flow path FP1 may include a supply flow path SFP and a recovery flow path CFP.

The supply flow path SFP may include a first supply flow path SFP1, a second supply flow path SFP2, and a third supply flow path SFP3. The first supply flow path SFP1, the second supply flow path SFP2, and the third supply flow path SFP3 may be sequentially arranged in a direction from the storage portion ST to the ink discharge module 80. The first supply flow path SFP1, the second supply flow path SFP2, and the third supply flow path SFP3 may be connected to one another. In an embodiment, for example, the first supply flow path SFP1, the second supply flow path SFP2, and the third supply flow path SFP3 may be integrally formed with each other as a single unitary and indivisible part. Thus, the ink INK introduced into the first supply flow path SFP1 from the storage portion ST may sequentially flow onto the second supply flow path SFP2 and the third supply flow path SFP3 and may be supplied to the ink discharge module 80.

The second supply flow path SFP2 may be branched into 2 parts from the first supply flow path SFP1. The second supply flow path SFP2 divided into 2 parts may be symmetrical to each other. The cross-sections of the second supply flow path SFP2 divided into 2 parts may be identical to each other. Thus, while the ink INK flows into the second supply flow path SFP2 from the first supply flow path SFP1, the ink INK may be equally distributed into the second supply flow path SFP2 branched into 2 parts. Thus, the flow rate, flow speed and pressure of the ink INK flowing onto the second supply flow path SFP2 branched into 2 parts may be identical to each other.

The third supply flow path SFP3 may connect the second supply flow path SFP2 to a plurality of head portions 81. The number of the plurality of head portions 81 may be 2ⁿ⁺¹ (where n is a natural number). For convenience of description, hereinafter, an embodiment, where the number of the plurality of head portions 81 is 4 (where n=1) as shown in FIG. 2, will be described.

The third supply flow path SFP3 may be connected to each of four head portions 81. The third supply flow path SFP3 may be branched into 2 parts from the second supply flow path SFP2. The third supply flow path SFP3 branched into 2 parts may be arranged in two pairs. That is, one pair of the third supply flow paths SFP3 may connect a corresponding one of the second supply flow path SFP2 branched into 2 parts to two head portions 81. Also, another one pair of the third supply flow paths SFP3 may connect a corresponding one of the second supply flow path SFP2 branched into 2 parts to the remaining two head portions 81.

The third supply flow path SFP3 divided into 2 parts may be symmetrical to each other. The cross-sections of the third supply flow path SFP3 divided into 2 parts may be identical to each other. Thus, while the ink INK flows onto the third supply flow path SFP3 from the second supply flow path SFP2, the ink INK may be equally distributed into the third supply flow path SFP3 branched into 2 parts. Thus, the flow rate, flow speed and pressure of the ink INK flowing onto the third supply flow path SFP3 branched into 2 parts may be identical to each other.

The sum of areas of the cross-sections of the second supply flow path SFP2 branched into 2 parts may be identical to an area of the cross-section of the first supply flow path SFP1. In an embodiment, for example, where the shape of the cross-section of the supply flow path SFP is a circular shape, a length of a diameter of a cross-section of the first supply flow path SFP1 may be v2 times of a length of a diameter of the cross-section of the second supply flow path SFP2. Thus, while the ink INK flows onto the supply flow path SFP, there may be small or no changes in flow rate at a boundary between the first supply flow path SFP1 and the second supply flow path SFP2. Thus, the flow stability of the ink INK flowing onto the supply flow path SFP may be enhanced.

The sum of areas of the cross-sections of the third supply flow path SFP3 branched into 2 parts may be identical to an area of the cross-section of the second supply flow path SFP2. In an embodiment, for example, where the shape of the cross-section of the supply flow path SFP is a circular shape, a length of a diameter of a cross-section of the second supply flow path SFP2 may be v2 times of a length of a diameter of the cross-section of the third supply flow path SFP3. Thus, while the ink INK flows onto the supply flow path SFP, there may be small or no changes in flow rate at a boundary between the second supply flow path SFP2 and the third supply flow path SFP3. Thus, the flow stability of the ink INK flowing onto the supply flow path SFP may be enhanced.

The first supply flow path SFP1 may include a first first supply flow path portion (hereinafter, will be referred to as “1st-1 supply flow path portion”) SFP1-1 and a second first supply flow path portion (hereinafter, will be referred to as “1st-2 supply flow path portion”) SFP1-2.

The 1st-1 supply flow path portion SFP1-1 may be connected to the storage portion ST. The 1st-1 supply flow path portion SFP1-1 may include or be made of a flexible material. Thus, the 1st-1 supply flow path portion SFP1-1 may have various shapes according to the shape, configuration or position of an apparatus (see 1 of FIG. 1) of manufacturing a display device. That is, the space utility of the 1st-1 supply flow path portion SFP1-1 may be enhanced.

The 1st-2 supply flow path SFP1-2 may connect the 1st-1 supply flow path portion SFP1-1 to the second supply flow path SFP2. The 1st-2 supply flow path portion SFP1-2 may include or be made of a solid material. Also, the 1st-2 supply flow path portion SFP1-2 may have a straight line shape. In an embodiment, for example, the shape of the 1st-2 supply flow path portion SFP1-2 may be a cylindrical shape. Thus, a phenomenon that, while the ink INK flowing in the 1st-2 supply flow path portion SFP1-2 is branched by the second supply flow path SFP2, the ink INK is formed to either side or vortex is formed, may be reduced. That is, the flow stability of the ink INK may be enhanced.

Each part of the second supply flow path SFP2 branched into 2 parts may include a first second supply flow path portion (hereinafter, will be referred to as “2nd-1 supply flow path portion”) SFP2-1 and a second second supply flow path portion (hereinafter, will be referred to as “2nd-2 supply flow path portion”) SFP2-2.

The 2nd-1 supply flow path portion SFP2-1 may be connected to the first supply flow path SFP1. The 2nd-1 supply flow path portion SFP2-1 may include or be made of a solid material. Thus, when the ink INK flows onto the 2nd-1 supply flow path portion SFP2-1, the flow stability of the ink INK may be enhanced. Also, the 2nd-1 supply flow path portion SFP2-1 may have a curved shape. In an embodiment, for example, the 2nd-1 supply flow path portion SFP2-1 may have a curved shape with a tangent form (i.e., a tangent graph-like form). Thus, flow resistance generated while the ink INK flows, may be effectively reduced.

The 2nd-2 supply flow path SFP2-2 may connect the 2nd-1 supply flow path portion SFP2-1 to the third supply flow path SFP3. The 2nd-2 supply flow path portion SFP2-2 may include or be made of a solid material. Also, the 2nd-2 supply flow path portion SFP2-2 may have a straight line shape. In an embodiment, for example, the shape of the 2nd-2 supply flow path portion SFP2-2 may be a cylindrical shape. Thus, a phenomenon that, while the ink INK flowing in the 2nd-2 supply flow path portion SFP2-2 is branched by the third supply flow path SFP3, the ink INK is formed to either side or vortex is formed, may be reduced. That is, the flow stability of the ink INK may be enhanced.

Each part of the third supply flow path SFP3 branched into 2 parts may include a first third supply flow path portion (hereinafter, will be referred to as “3rd-1 supply flow path portion”) SFP3-1 and a second third supply flow path portion (hereinafter, will be referred to as “3rd-2 supply flow path portion”) SFP3-2.

The 3rd-1 supply flow path portion SFP3-1 may be connected to the second supply flow path SFP2. The 3rd-1 supply flow path portion SFP3-1 may include or be made of a solid material. Thus, when the ink INK flows in the 3rd-1 supply flow path portion SFP3-1, the flow stability of the ink INK may be enhanced. Also, the 3rd-1 supply flow path portion SFP3-1 may have a curved shape. In an embodiment, for example, the 3rd-1 supply flow path portion SFP3-1 may have a curved shape with a tangent form. Thus, flow resistance generated while the ink INK flows, may be effectively reduced.

The 3rd-2 supply flow path SFP3-2 may connect the 3rd-1 supply flow path portion SFP3-1 to four head portions 81. The 3rd-2 supply flow path portion SFP3-2 may include or be made of a solid material. Also, the 3rd-2 supply flow path portion SFP3-2 may have a straight line shape. In an embodiment, for example, the shape of the 3rd-2 supply flow path portion SFP3-2 may be a cylindrical shape. Thus, a phenomenon that, while the ink INK flowing in the 3rd-2 supply flow path portion SFP3-2 is supplied to the ink discharge module 80, the ink INK is formed to either side or vortex is formed, may be reduced. That is, the flow stability of the ink INK may be enhanced.

The recovery low path CFP may include a first recovery flow path CFP1, a second recovery flow path CFP2, and a third recovery flow path CFP3. The first recovery flow path CFP1, the second recovery flow path CFP2, and the third recovery flow path CFP3 may be sequentially arranged in a direction from the storage portion ST to the ink discharge module 80. The first recovery flow path CFP1, the second recovery flow path CFP2, and the third recovery flow path CFP3 may be connected to one another. For example, the first recovery flow path CFP1, the second recovery flow path CFP2, and the third recovery flow path CFP3 may be integrally formed with each other as a single unitary and indivisible part. The first recovery flow path CFP1 may be connected to the storage portion ST. Thus, the ink INK introduced into the third recovery flow path CFP3 from the supply flow path SFP may sequentially flow onto the second recovery flow path CFP2 and the first recovery flow path CFP1 and may be recovered into a supply portion.

The second recovery flow path CFP2 may be branched into 2 parts from the first recovery flow path CFP1. The second recovery flow path CFP2 divided into 2 parts may be symmetrical to each other. The cross-sections of the second recovery flow path CFP2 divided into 2 parts may be identical to each other.

The third recovery flow path CFP3 may connect the second recovery flow path CFP2 to the supply flow path SFP. The third recovery flow path CFP3 may be branched into 2 parts from the second recovery flow path CFP2. The third recovery flow path CFP3 branched into 2 parts may be arranged in two pairs. That is, one pair of the third recovery flow paths CFP3 may connect a corresponding one of the second recovery flow path CFP2 branched into 2 parts to the third supply flow path SFP3. That is, one pair of the third recovery flow paths CFP3 may connect a corresponding one of the second recovery flow path CFP2 branched into 2 parts to another pair of the third supply flow path SFP3.

The third recovery flow path CFP3 divided into 2 parts may be symmetrical to each other. The cross-sections of the third recovery flow path CFP3 divided into 2 parts may be identical to each other.

The sum of areas of the cross-sections of the second recovery flow path CFP2 branched into 2 parts may be identical to an area of the cross-section of the first recovery flow path CFP1. In an embodiment, for example, when the shape of the cross-section of the recovery flow path CFP is a circular shape, a length of a diameter of a cross-section of the first recovery flow path CFP1 may be v2 times of a length of a diameter of the cross-section of the second recovery flow path CFP2. Thus, while the ink INK flows onto the recovery flow path CFP, there may be small or no changes in flow rate at a boundary between the first recovery flow path CFP1 and the second recovery flow path CFP2.

The sum of areas of the cross-sections of the third recovery flow path CFP3 branched into 2 parts may be identical to an area of the cross-section of the second recovery flow path CFP2. In an embodiment, for example, when the shape of the cross-section of the recovery flow path CFP is a circular shape, a length of a diameter of a cross-section of the second recovery flow path CFP2 may be \sqrt{2} times of a length of a diameter of the cross-section of the third recovery flow path CFP3. Thus, while the ink INK flows onto the recovery flow path CFP, there may be small or no changes in flow rate at a boundary between the second recovery flow path CFP2 and the third recovery flow path CFP3.

In such an embodiment, while the ink INK is introduced from the supply flow path SFP to the recovery flow path CFP, the ink INK may be uniformly introduced into each of two pairs of third recovery flow paths CFP3 branched into 2 parts. Thus, the flow rate, flow speed, and pressure of the ink INK supplied to the plurality of head portions 81 through the supply flow path SFP may be identical to each other. That is, the flow stability of the ink INK supplied to the plurality of head portions 81 may be enhanced.

The first recovery flow path CFP1 may include a first first recovery flow path portion (hereinafter, will be referred to as “1st-1 recovery flow path portion”) CFP1-1 and a second first recovery flow path portion (hereinafter, will be referred to as “1st-2 recovery flow path portion”) CFP1-2.

The 1st-1 recovery flow path portion CFP1-1 may be connected to the storage portion ST. The 1st-1 recovery flow path portion CFP1-1 may include or be made of a flexible material. Thus, the 1st-1 supply flow path portion CFP1-1 may have various shapes according to the shape, configuration or position of the apparatus (see 1 of FIG. 1) of manufacturing the display device. That is, the space utility of the 1st-1 recovery flow path portion CFP1-1 may be enhanced.

The 1st-2 recovery flow path CFP1-2 may connect the 1st-1 recovery flow path portion CFP1-1 to the second recovery flow path CFP2. The 1st-2 recovery flow path portion CFP1-2 may include or be made of a solid material. Also, the 1st-2 recovery flow path portion CFP1-2 may have a straight line shape. In an embodiment, for example, the shape of the 1st-2 recovery flow path portion CFP1-2 may be a cylindrical shape. Thus, a phenomenon that, while the ink INK flowing in the second recovery flow path portion CFP2 branched is merged into the 1st-2 recovery flow path CFP, the ink INK is formed to either side or vortex is formed, may be reduced. That is, the flow stability of the ink INK may be enhanced.

Each part of the second recovery flow path CFP2 branched into 2 parts may include a first second recovery flow path portion (hereinafter, will be referred to as “2nd-1 recovery flow path portion”) CFP2-1 and a second second recovery flow path portion (hereinafter, will be referred to as “2nd-2 recovery flow path portion”) CFP2-2.

The 2nd-1 recovery flow path portion CFP2-1 may be connected to the first recovery flow path CFP1. The 2nd-1 recovery flow path portion CFP2-1 may include or be made of a solid material. Thus, when the ink INK flows in the 2nd-1 recovery flow path portion CFP2-1, the flow stability of the ink INK may be enhanced. Also, the 2nd-1 recovery flow path portion CFP2-1 may have a curved shape. In an embodiment, for example, the 2nd-1 recovery flow path portion CFP2-1 may have a curved shape with a tangent form. Thus, flow resistance generated while the ink INK flows, may be effectively reduced.

The 2nd-2 recovery flow path CFP2-2 may connect the 2nd-1 recovery flow path portion CFP2-1 to the third recovery flow path CFP3. The 2nd-2 recovery flow path portion CFP2-2 may include or be made of a solid material. Also, the 2nd-2 recovery flow path portion CFP2-2 may have a straight line shape. In an embodiment, for example, the shape of the 2nd-2 recovery flow path portion CFP2-2 may be a cylindrical shape. Thus, a phenomenon that, while the ink INK flowing in the third recovery flow path portion CFP3 branched is merged into the 2nd-2 recovery flow path CFP, the ink INK is formed to either side or vortex is formed, may be reduced. That is, the flow stability of the ink INK may be enhanced.

The third recovery flow path portion CFP3 may include or be made of a solid material. Thus, when the ink INK flows onto the third recovery flow path CFP3, the flow stability of the ink INK may be enhanced. Also, the third recovery flow path CFP3 may have a curved shape. In an embodiment, for example, the third recovery flow path CFP3 may have a curved shape with a tangent form. Thus, flow resistance generated while the ink INK flows, may be effectively reduced.

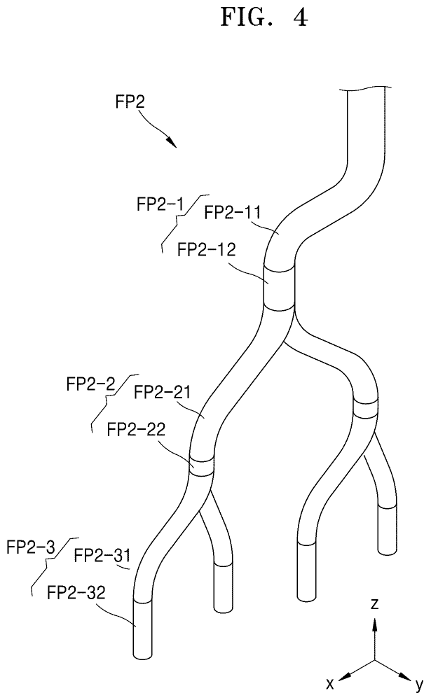

FIG. 4 is a perspective view schematically illustrating a second flow path FP2 according to an embodiment.

Referring to FIGS. 2 and 4, in an embodiment, the second flow path FP2 may include a first second flow path (hereinafter, will be referred to as “2nd-1 flow path”) FP2-1, a second second flow path (hereinafter, will be referred to as “2nd-2 flow path”) FP2-2, and a third second flow path (hereinafter, will be referred to as “2nd-3 flow path”) FP2-3.

The 2nd-1 flow path FP2-1, the 2nd-2 flow path FP2-2, and the 2nd-3 flow path FP2-3 may be sequentially arranged in a direction from the storage portion ST to the ink discharge module 80. The 2nd-1 flow path FP2-1, the 2nd-2 flow path FP2-2, and the 2nd-3 flow path FP2-3 may be connected to each other. In an embodiment, for example, the 2nd-1 flow path FP2-1, the 2nd-2 flow path FP2-2, and the 2nd-3 flow path FP2-3 may be integrally formed with each other as a single unitary and indivisible part. The 2nd-1 flow path FP2-1 may be connected to the storage portion ST. Thus, the ink INK introduced into the 2nd-3 flow path FP2-3 from the ink discharge unit may sequentially flow onto the 2nd-2 flow path FP2-2 and the 2nd-1 flow path FP2-1 and may be introduced into the supply portion.

The 2nd-2 flow path FP2-2 may be branched into 2 parts from the 2nd-1 flow path FP2-1. The 2nd-2 flow path FP2-2 divided into 2 parts may be symmetrical to each other. The cross-sections of the 2nd-2 flow path FP2-2 divided into 2 parts may be identical to each other.

The 2nd-3 flow path FP2-3 may connect the 2nd-2 flow path FP2-2 to a plurality of head portions 81. The 2nd-3 flow path FP2-3 may be branched into 2 parts from the 2nd-2 flow path FP2-2. The 2nd-3 flow path FP2-3 divided into 2 parts may be arranged in two pairs. That is, one pair of the 2nd-3 flow paths FP2-3 may connect a corresponding one of the 2nd-2 flow paths FP2-2 branched into 2 parts to two head portions 81. Also, another one pair of the 2nd-3 flow paths FP2-3 may connect a corresponding one of the 2nd-2 flow paths FP2-2 branched into 2 parts to two head portions 81.

The 2nd-3 flow path FP2-3 divided into 2 parts may be symmetrical to each other. The cross-sections of the 2nd-3 flow path FP2-3 divided into 2 parts may be identical to each other.

The sum of areas of the cross-sections of the 2nd-2 flow path FP2-2 branched into 2 parts may be identical to an area of the cross-section of the 2nd-1 flow path FP2-1. In an embodiment, for example, when the shape of the cross-section of the second flow path FP2 is a circular shape, a length of a diameter of a cross-section of the 2nd-1 flow path FP2-1 may be v2 times of a length of a diameter of the cross-section of the 2nd-2 flow path FP2-2. Thus, while the ink INK flows onto the second flow path FP2, there may be small or no changes in flow rate at a boundary between the 2nd-1 flow path FP2-1 and the 2nd-2 flow path FP2-2.

The sum of areas of the cross-sections of the 2nd-3 flow path FP2-3 branched into 2 parts may be identical to an area of the cross-section of the 2nd-2 flow path FP2-2. In an embodiment, for example, when the shape of the cross-section of the second flow path FP2 is a circular shape, a length of a diameter of a cross-section of the 2nd-2 flow path FP2-2 may be \sqrt{2} times of a length of a diameter of the cross-section of the 2nd-3 flow path FP2-3. Thus, while the ink INK flows onto the second flow path FP2, there may be small or no changes in flow rate at a boundary between the 2nd-2 flow path FP2-2 and the 2nd-3 flow path FP2-3.

In such an embodiment, while the ink INK is introduced from the ink discharge module 80 to the second supply flow path FP2, the ink INK may be uniformly introduced into each of two pairs of 2nd-3 flow paths FP2-3 branched into 2 parts. Also, while the ink INK introduced into the 2nd-3 flow path FP2-3 flows onto the 2nd-2 flow path FP2-2 and the 2nd-1 flow path FP2-1, the flow rate, speed and pressure of the ink INK may be identical to each other. That is, the flow stability of the ink INK flowing onto the second flow path FP2 may be enhanced.

The 2nd-1 flow path FP2-1 may include a first sub flow path portion (hereinafter, will be referred to as “2nd-11 flow path portion”) FP2-11 and a second sub flow path portion (hereinafter, will be referred to as “2nd-12 flow path portion”) FP2-12.

The 2nd-11 flow path FP2-11 may be connected to the storage portion ST. The 2nd-11 flow path portion FP2-11 may include or be made of a flexible material. Thus, the 2nd-11 flow path portion FP2-11 may have various shapes according to the shape, configuration or position of the apparatus (see 1 of FIG. 1) of manufacturing the display device. That is, the space utility of the 2nd-11 flow path portion FP2-11 may be enhanced.

The 2nd-12 flow path FP2-12 may connect the 2nd-11 flow path portion FP2-11 to the 2nd-12 flow path portion FP2-12. The 2nd-12 flow path portion FP2-12 may include be made of a solid material. Also, the 2nd-12 flow path portion FP2-12 may have a straight line shape. In an embodiment, for example, the shape of the 2nd-12 flow path portion FP2-12 may be a cylindrical shape. Thus, a phenomenon that, while the ink INK flowing in the 2nd-2 flow path FP2 branched is merged into the 2nd-12 flow path portion FP2-12, the ink INK is formed to either side or vortex is formed, may be reduced. That is, the flow stability of the ink INK may be enhanced.

Each part of the 2nd-2 flow path FP2-2 branched into 2 parts may include a first sub flow path portion (hereinafter, will be referred to as “2nd-21 flow path portion”) FP2-21 and a second sub flow path portion (hereinafter, will be referred to as “2nd-22 flow path portion”) FP22-2.

The 2nd-21 flow path FP2-21 may be connected to the 2nd-1 flow path FP2-1. The 2nd-21 flow path portion FP2-21 may include or be made of a solid material. Thus, when the ink INK flows onto the 2nd-21 flow path portion FP2-21, the flow stability of the ink INK may be enhanced. Also, the 2nd-21 flow path portion FP2-21 may have a straight line shape. In an embodiment, for example, the 2nd-21 flow path portion FP2-21 may have a curved shape with a tangent form. Thus, flow resistance generated while the ink INK flows, may be effectively reduced.

The 2nd-22 flow path FP2-22 may connect the 2nd-21 flow path portion FP2-21 to the 2nd-3 flow path FP2-3. The 2nd-22 flow path portion FP2-22 may include or be made of a solid material. Also, the 2nd-22 flow path portion FP2-22 may have a straight line shape. In an embodiment, for example, the shape of the 2nd-22 flow path portion FP2-22 may be a cylindrical shape. Thus, a phenomenon that, while the ink INK flowing onto the 2nd-3 flow path FP2-3 branched is merged into the 2nd-22 flow path portion FP2-22, the ink INK is formed to either side or vortex is formed, may be reduced. That is, the flow stability of the ink INK may be enhanced.

Each part of the 2nd-3 flow path FP2-3 branched into 2 parts may include a first sub flow path portion (hereinafter, will be referred to as “2nd-31 flow path portion”) FP2-31 and a second sub flow path portion (hereinafter, will be referred to as “2nd-32 flow path portion”) FP2-32.

The 2nd-31 flow path FP2-31 may be connected to the 2nd-2 flow path FP2-2. The 2nd-31 flow path portion FP2-31 may include or be made of a solid material. Thus, when the ink INK flows in the 2nd-31 flow path portion FP2-31, the flow stability of the ink INK may be enhanced. Also, the 2nd-31 flow path portion FP2-31 may have a straight line shape. In an embodiment, for example, the 2nd-31 flow path portion FP2-31 may have a curved shape with a tangent form. Thus, flow resistance generated while the ink INK flows, may be effectively reduced.

The 2nd-32 flow path FP2-32 may connect the 2nd-31 flow path portion FP2-31 to the storage portion ST. The 2nd-32 flow path portion FP2-32 may include or be made of a solid material. Also, the 2nd-32 flow path portion FP2-32 may have a straight line shape. In an embodiment, for example, the shape of the 2nd-32 flow path portion FP2-32 may be a cylindrical shape. Thus, a phenomenon that, while the ink INK flows onto the 2nd-32 flow path branched from the storage portion ST, the ink INK is formed either side or vortex is formed, may be reduced. That is, the flow stability of the ink INK may be enhanced.

FIGS. 2 through 4 illustrate embodiments where the number of head portions 81 is four. However, as described above, this is just an example, and the number of the head portions 81 may be 2ⁿ⁺¹ (where n is a natural number). In an embodiment, for example, the number of head portions 81 may also be 8 (where n=2).

In an embodiment where eight head portions 81 are provided, the supply flow path SFP may further include a fourth supply flow path (not shown), and the recovery flow path CFP may further include a fourth recovery flow path CFP, and the second flow path FP2 may further include a fourth second flow path.

In such an embodiment, first, in the supply flow path SFP, the second supply flow path SFP2, which is branched into two parts, may be connected to the first supply flow path SFP1, a fourth supply flow path (not shown) branched into two parts may be connected to each part of the second supply flow paths SFP2 branched into two parts, the third supply flow path SFP3 branched into two parts may be connected to each part of the fourth supply flow path (not shown) branched into two parts, and finally, the third supply flow path SFP3 may be connected to the plurality of head portions 81.

In addition, in the recovery flow path CFP, the second recovery flow path CFP2, which is branched into two parts, may be connected to the first recovery flow path CFP1, a fourth recovery flow path CFP branched into two parts may be connected to each part of the second recovery flow paths CFP2 branched into two parts, the third recovery flow path CFP3 branched into two parts may be connected to each part of the fourth recovery flow path CFP branched into two parts, and finally, the third recovery flow path CFP3 may be connected to the third supply flow path SFP3.

Also, in the second flow path FP2, the 2nd-2 flow path FP2-2, which is branched into two parts, may be connected to the 2nd-1 flow path FP2-1, a fourth supply flow path (not shown) branched into two parts may be connected to each part of the 2nd-2 flow paths FP2-2 branched into two parts, a 2nd-3 flow path FP2-3 branched into two parts may be connected to each part of the fourth supply flow path (not shown) branched into two parts, and finally, the 2nd-3 flow path FP2-3 may be connected to the plurality of head portions 81.

In addition, the number of head portions 81 may also be 16 (where n=3) or 32 (where n=4).

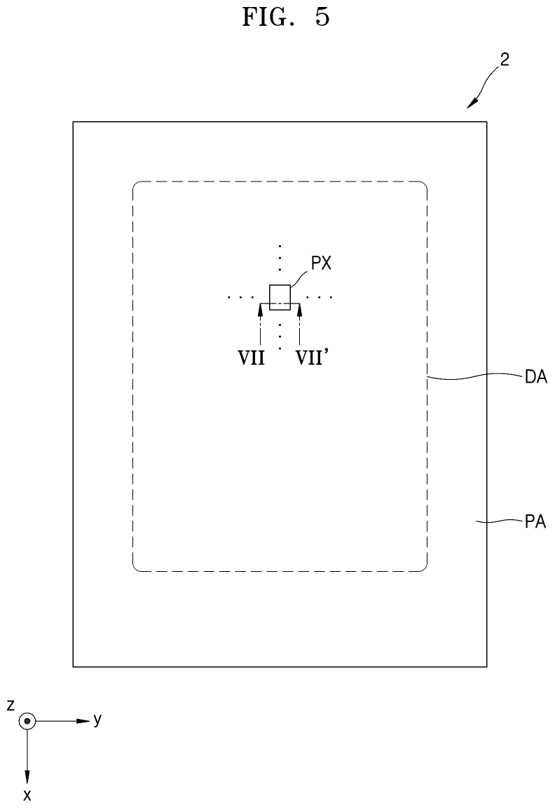

FIG. 5 is a plan view schematically illustrating a display device according to an embodiment.

Referring to FIG. 5, a display device 2 according to an embodiment may include a display area DA and a peripheral area PA outside the display area DA. The display device 2 may provide an image through an array of a plurality of pixels that are two-dimensionally arranged in an x-y plane in the display area DA.

The peripheral area PA may be an area in which no image is provided and may entirely or partially surround the display area DA. Drivers for providing electrical signals or power in each pixel circuit corresponding to each pixel PX may be arranged in the peripheral area PA. A pad that is an area in which an electronic device or a printed circuit board may be electrically connected, may be included in the peripheral area PA.

Hereinafter, embodiments where the display device 2 that is a light-emitting element includes an organic light-emitting diode (OLED), but the display device 2 of the disclosure is not limited thereto. In another embodiment, the display device 2 may be a light-emitting display device including an inorganic light-emitting diode, i.e., an inorganic light-emitting display device. The inorganic light-emitting diode may include a PN diode including materials based on an inorganic material semiconductor. When a voltage is applied to a PN junction diode in a forward direction, holes and electrons may be injected, and energy generated by re-combination of the holes and the electrons may be converted into light energy so that light having a certain color may be emitted. The above-described inorganic light-emitting diode may have a width of several to several hundreds of micrometers, and in some embodiments, the inorganic light-emitting diode may be referred to as a micro light-emitting diode (LED). In another embodiment, the display device 2 may be a quantum dot light-emitting display device.

The display device 2 may be applied to various products, such as mobile phones, smart phones, table personal computers (PCs), mobile communication terminals, electronic notes, electronic books, portable multimedia players (PMPs), navigation devices, ultra mobile PCs, televisions (TVs), laptop computers, monitors, billboards, Internet of Things (IoT), or the like. In addition, the display device 2 according to an embodiment may be used for a wearable device such as a smart watch, a watch phone, a glasses type display, or a head mounted display (HMD). In addition, the display device 2 according to an embodiment may be used as an instrument panel of a vehicle, and a center information display (CID) display arranged on a center fascia or a dashboard of a vehicle, a room mirror display for replacing a side mirror of a vehicle, and a display screen that is entertainment for the rear seat of the vehicle and is arranged on the rear surface of the front seat.

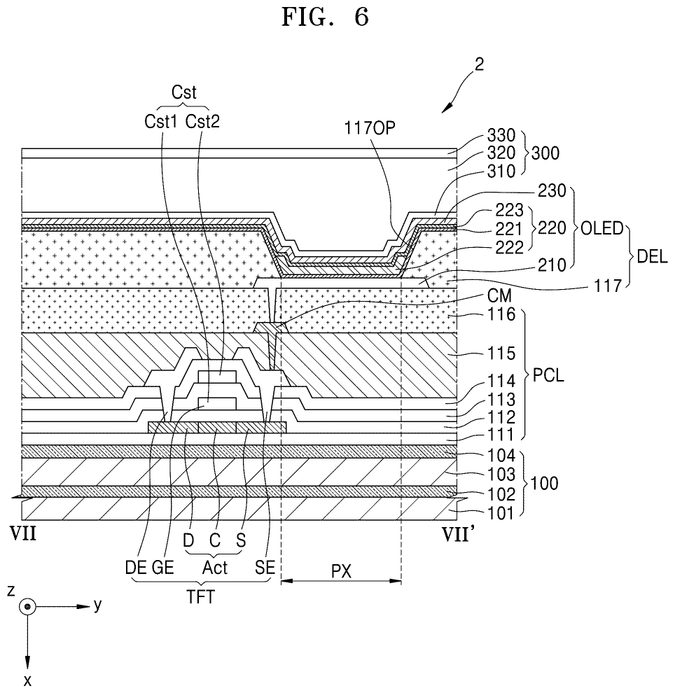

FIG. 6 is a cross-sectional view schematically illustrating a display device according to an embodiment and may correspond to a cross-section of the display device taken along line VII-VII′ of FIG. 5.

Referring to FIG. 6, an embodiment of the display device 2 may have a stack structure of a substrate 100, a pixel circuit layer PC, a display element layer DEL, and an encapsulation layer 300.

The substrate 100 may have a multi-layered structure including a layer including a polymer resin and an inorganic layer (not shown). For example, the substrate 100 may include a base layer including the polymer resin and a barrier layer of an inorganic insulating layer. In an embodiment, for example, the substrate 100 may include a first base layer 101, a first barrier layer 102, a second base layer 103, and a second barrier layer 104, which are sequentially stacked. The first base layer 101 and the second base layer 103 may include polyimide (PI), polyethersulfone (PES), polyarylate, polyetherimide (PEI), polyethyelenene napthalate (PEN), polyethyeleneterepthalate (PET), polyphenylene sulfide (PPS), polycarbonate, cellulose triacetate (TAC) or/and cellulose acetate propionate (CAP). The first barrier layer 102 and the second barrier layer 104 may include an inorganic insulating material such as silicon oxide, silicon oxynitride and/or silicon nitride. The substrate 100 may have flexible characteristics.

The pixel circuit layer PC may be arranged on the substrate 100. FIG. 6 illustrates an embodiment where the pixel circuit layer PC includes a thin-film transistor TFT, and a buffer layer 111, a first gate insulating layer 112, a second gate insulating layer 113, an interlayer insulating layer 114, a first planarization insulating layer 115, and a second planarization insulating layer 116, which are arranged under or/and on components of the thin-film transistor TFT.

The buffer layer 111 may reduce or block penetration of foreign substances, moisture or external air from the lower portion of the substrate 100, and may provide a flat surface onto the substrate 100. The buffer layer 111 may include an inorganic insulating material such as silicon oxide, silicon oxynitride, or silicon nitride, and may have a single layer or multi-layered structure, each layer therein including at least one selected from the above-described materials.

The thin-film transistor TFT on the buffer layer 111 may include a semiconductor layer Act, and the semiconductor layer Act may include polysilicon (Poly-Si). Alternatively, the semiconductor layer Act may include amorphous silicon (a-Si), an oxide semiconductor, or an organic semiconductor, etc. The semiconductor layer Act may include a channel region C, and a drain region D and a source region S, which are at opposing sides of the channel region C. A gate electrode GE may overlap the channel region C.

The gate electrode GE may include a low-resistance metal material. The gate electrode GE may include a conductive material including molybdenum (Mo), aluminum (Al), copper (Cu), titanium (Ti), or the like, and may have a multi-layered or single layer structure, each layer therein including at least one selected from the materials described above.

The first gate insulating layer 112 between the semiconductor layer Act and the gate electrode GE may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOx). Here, zinc oxide (ZnOₓ) may be zinc oxide (ZnO) and/or peroxide (ZnO₂).

The second gate insulating layer 113 may be provided to cover the gate electrode GE. The second gate insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ), similarly to the first gate insulating layer 112. Here, zinc oxide (ZnOx) may be zinc oxide (ZnO) and/or peroxide (ZnO₂).

An upper electrode Cst2 of a storage capacitor Cst may be arranged above the second gate insulating layer 113. The upper electrode Cst2 may overlap the gate electrode GE thereunder. In such an embodiment, the gate electrode GE, and the upper electrode Cst2, which overlap each other with the second gate insulating layer 113 therebetween, may form or collectively define the storage capacitor Cst. That is, the gate electrode GE may function as a lower electrode Cst1 of the storage capacitor Cst.

In such an embodiment, the storage capacitor Cst and the thin-film transistor TFT may overlap each other. In some embodiments, the storage capacitor Cst may not overlap the thin-film transistor TFT.

The upper electrode Cst2 may include aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single layer or multi-layered structure, each layer therein including at least one selected from the materials described above.

The interlayer insulating layer 114 may be provided to cover the upper electrode Cst2. The interlayer insulating layer 114 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOx) may be zinc oxide (ZnO) and/or peroxide (ZnO₂). The interlayer insulating layer 114 may have a single layer or multi-layered structure, each layer therein including at least one selected from the above-described inorganic insulating materials.

The drain electrode DE and the source electrode SE may be located on the interlayer insulating layer 114. The drain electrode DE and the source electrode SE may be connected to the drain region D and the source region S, respectively, through a contact hole defined or formed in insulating layers thereunder. The drain electrode DE and the source electrode SE may include a high conductive material. The drain electrode DE and the source electrode SE may include a conductive material including molybdenum (Mo), aluminum (AI), copper (Cu), titanium (Ti), or the like, and may have a multi-layered or single layer structure, each layer therein including at least one selected from the materials described above. In an embodiment, the drain electrode DE and the source electrode SE may have a multi-layered structure of Ti/Al/Ti.

The first planarization insulating layer 115 may cover the drain electrode DE and the source electrode SE. The first planarization insulating layer 115 may include an organic insulating material such as a general purpose polymer such as polymethylmethacrylate (PMMA) or polystyrene (PS), a polymer derivative having a phenol-based group, acryl-based polymer, imide-based polymer, aryl ether-based polymer, amide-based polymer, fluorine-based polymer, p-xylene-based polymer, vinyl alcohol-based polymer, and a blend thereof.

The second planarization insulating layer 116 may be arranged on the first planarization insulating layer 115. The second planarization insulating layer 116 may include a same material as the first planarization insulating layer 115, and may include an organic insulating material such as a general purpose polymer such as polymethylmethacrylate (PMMA) or polystyrene (PS), a polymer derivative having a phenol-based group, acryl-based polymer, imide-based polymer, aryl ether-based polymer, amide-based polymer, fluorine-based polymer, p-xylene-based polymer, vinyl alcohol-based polymer, and a blend thereof.

A display element layer DEL may be arranged on the pixel circuit layer PC having the structure described above. The display element layer DEL may include an organic light-emitting diode OLED as a display element (i.e., light-emitting device), and the organic light-emitting diode OLED may include a stack structure of a pixel electrode 210, an intermediate layer 220, and a common electrode 230. The organic light-emitting diode OLED may emit red, green, or blue light, for example, or may emit red, green, blue, or white light. The organic light-emitting diode OLED may emit light through an emission area, and the emission area may be defined as a pixel PX.

The pixel electrode 210 of the organic light-emitting diode OLED may be electrically connected to the thin-film transistor TFT through contact holes defined or formed in the second planarization insulating layer 116 and the first planarization insulating layer 115 and a contact metal CM arranged on the first planarization insulating layer 115.

In an embodiment, the pixel electrode 210 may include a transparent conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 21 may include a reflective layer including Ag, Mg, Al, Pt, Pd, Au, Ni, Nd, Ir, Cr, or a compound thereof. In another embodiment, the pixel electrode 210 may further include layers formed of ITO, IZO, ZnO or In₂O₃ on/under the above-described reflective layer.

A bank layer 117 provided with an opening 117OP for exposing the center of the pixel electrode 210 may be arranged on the pixel electrode 210. The bank layer 117 may include an organic insulating material and an inorganic insulating material. The opening 117OP may define an emission area of light emitted from the organic light-emitting diode OLED. In an embodiment, for example, the size/width of the opening 117OP may correspond to the size/width of the emission area. Thus, the size and/or width of the pixel PX may depend on the size and/or width of the opening 117OP of the bank layer 117.

The intermediate layer 220 may include a light-emitting layer 222 formed to correspond to the pixel electrode 210. The light-emitting layer 222 may include a polymer or a low molecular weight organic material emitting light of a certain color. Alternatively, the light-emitting layer 222 may include an inorganic light-emitting material or quantum dots.

In an embodiment, the intermediate layer 220 may include a first functional layer 221 and a second functional layer 223, which are arranged under and on the light-emitting layer 222. The first functional layer 221 may include, for example, a hole transport layer (HTL) or a HTL and a hole injection layer (HIL). The second functional layer 223 may be a component arranged above the light-emitting layer 222 and may include an electron transport layer (ETL) and/or an electron injection layer (EIL). The first functional layer 221 and/or the second functional layer 223 may be a common layer formed to entirely cover the substrate 100 similarly to the common electrode 230 to be described later.

The common electrode 230 may be arranged on the pixel electrodes 210 and may overlap the pixel electrodes 210. The common electrode 230 may include a conductive material having a low work function. In an embodiment, for example, the common electrode 230 may include a (semi-)transparent layer including Ag, Mg, Al, Pt, Pd, Au, Ni, Nd, Ir, Cr, Li, Ca or an alloy thereof. Alternatively, the common electrode 230 may further include a layer such as ITO, IZO, ZnO or In₂O₃ on the (semi-)transparent layer including the above-described materials. The common electrode 230 may be integrally or continuously formed over the substrate 100 entirely.

The encapsulation layer 300 may be arranged on the display element layer DEL and may cover the display element layer DEL. The encapsulation layer 300 may include at least one inorganic encapsulation layer and at least one organic encapsulation layer, and in an embodiment, FIG. 6 illustrates that the encapsulation layer 300 includes a first inorganic encapsulation layer 310, an organic encapsulation layer 320 and a second inorganic encapsulation layer 330, which are sequentially stacked.

The first inorganic encapsulation layer 310 and the second inorganic encapsulation layer 330 may include at least one inorganic material selected from aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acryl-based resin, an epoxy-based resin, polyimide, polyethylene, or the like. In an embodiment, the organic encapsulation layer 320 may include acrylate. The organic encapsulation layer 320 may be formed by hardening monomer or by coating polymer. The organic encapsulation layer 320 may have transparency.

Although not shown, a touch sensor layer may be arranged on the encapsulation layer 300, and an optical functional layer may be arranged on the touch sensor layer. The touch sensor layer may obtain coordinate information according to an external input, for example, a touch event. The optical functional layer may reduce reflectivity of light (external light) incident toward the display device from the outside and/or may enhance color purity of light emitted from the display device. In an embodiment, the optical functional layer may include a phase retarder and/or a polarizer. The phase retarder may be of a film type or liquid crystal coating type and may include a λ/2 phase retarder or a λ/4 phase retarder. The polarizer may also be of a film type or liquid crystal coating type. The film type may include an elongation type synthetic resin film, and the liquid crystal coating type may include liquid crystals arranged in a certain arrangement. The phase retarder and the polarizer may further include a protective film.

An adhesive member may be arranged between the touch electrode layer and the optical functional layer. The adhesive member may be general things known in this technical field without restrictions. The adhesive member may be a pressure sensitive adhesive (PSA).

In an embodiment, at least one selected from the pixel circuit layer PC, the display element layer DEL, and the encapsulation layer 300 may be formed by ink INK discharged from the ink discharge module 80 described above with reference to FIGS. 1 through 4.

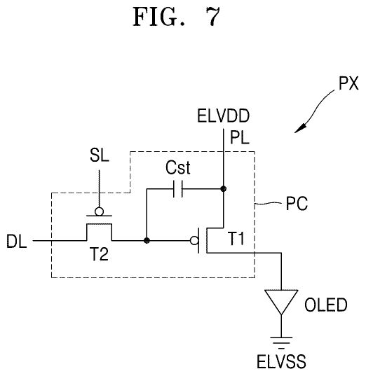

FIG. 7 is an equivalent circuit diagram of a pixel of a display panel according to an embodiment.

In an embodiment, each pixel PX may include a pixel circuit PC, a display element connected to the pixel circuit PC, for example, an organic light-emitting diode OLED. The pixel circuit PC may include a first thin-film transistor T1, a second thin-film transistor T2, and a storage capacitor Cst. Each pixel PX may emit, for example, red, green, blue, or white light through the organic light-emitting diode OLED.

The second thin-film transistor T2 may be a switching thin-film transistor, may be connected to a scan line SL and a data line DL, and may be configured to transmit a data voltage input from the data line DL in response to a switching voltage input from the scan line SL to the first thin-film transistor T1. The storage capacitor Cst may be connected to the second thin-film transistor T2 and a driving voltage line PL and may store a voltage corresponding to a difference between a voltage transmitted from the second thin-film transistor T2 and a first power supply voltage ELVDD supplied to the driving voltage line PL.

The first thin-film transistor T1 may be a driving thin-film transistor, may be connected to the driving voltage line PL and the storage capacitor Cst, and may control a driving current flowing through the organic light-emitting diode OLED from the driving voltage line PL in response to a voltage value stored in the storage capacitor Cst. The organic light-emitting diode OLED may emit light having certain luminance by using the driving current. An opposite electrode (e.g., a cathode) of the organic light-emitting diode OLED may receive a second power supply voltage ELVSS.

FIG. 7 illustrates an embodiment where the pixel circuit PC includes two thin-film transistors and one storage capacitor, and embodiments are not limited thereto. The number of thin-film transistors and the number of storage capacitors may be variously changed according to the design of the pixel circuit PC. In an embodiment, for example, the pixel circuit PC may further include four, five or more thin-film transistors in addition to the two thin-film transistors described above.

According to one or more embodiments of an apparatus for manufacturing a display device, ink is not precipitated during an ink supply process, and a target ink inflow flow rate desired by an ink discharge module may be achieved.

The effects of the disclosure are not limited to the aforementioned objectives, and other effects not mentioned can be clearly understood by a person skilled in the art from the following description.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing a display device, the apparatus comprising:
a stage on which a display substrate is arranged;
an ink discharge module which discharges ink onto the display substrate; and
an ink supply module which supplies ink to the ink discharge module,
wherein the ink supply module comprises:
a storage portion in which ink is stored;
a first flow path connecting the storage portion to the ink discharge module in a way such that ink stored in the storage portion flows into the ink discharge module; and
a second flow path connecting the storage portion to the ink discharge module in a way such that ink supplied to the ink discharge module flows into the storage portion, and
wherein the first flow path comprises:
a supply flow path having a first end connected to the storage portion and a second end connected to the ink discharge module in a way such that ink introduced from the storage portion is supplied to the ink discharge module; and
a recovery flow path having a first end connected to the supply flow path and a second end connected to the storage portion in a way such that ink introduced into the supply flow path is recovered into the storage portion.

2. The apparatus of claim 1, wherein
the ink discharge module comprises a plurality of head portions configured to spray ink, wherein the number of the plurality of head portions is 2ⁿ⁺¹, wherein n is a natural number, and
the supply flow path comprises:
a first supply flow path through which ink is introduced from the storage portion;
a second supply flow path branched into 2 parts from the first supply flow path; and
a third supply flow path connecting the second supply flow path to the plurality of head portions.

3. The apparatus of claim 2, wherein shapes of cross-sections of the second supply flow path branched into 2 parts are identical to each other.

4. The apparatus of claim 3, wherein a sum of areas of cross-sections of the second supply flow path branched into 2 parts is identical to an area of a cross-section of the first supply flow path.

5. The apparatus of claim 2, wherein the first supply flow path comprises:
a first first supply flow path portion including a flexible material and connected to the storage portion; and
a second first supply flow path portion including a solid material and connecting the first first supply flow path portion to the second supply flow path.

6. The apparatus of claim 5, wherein the second first supply flow path portion has a straight line shape.

7. The apparatus of claim 2, wherein each part of the second supply flow path branched into 2 parts comprises:
a first second supply flow path portion connected to the first supply flow path and having a curved shape; and
a second second supply flow path portion connecting the first second supply flow path portion to the third supply flow path and having a straight line shape.

8. The apparatus of claim 2, wherein the ink supply module further comprises a first pump arranged on the first supply flow path in a way such that ink introduced into the supply flow path flows into the ink discharge module.

9. The apparatus of claim 2, wherein the recovery flow path connects the storage portion to the third supply flow path.

10. The apparatus of claim 9, wherein the recovery flow path comprises:
a first recovery flow path connected to the storage portion;
a second recovery flow path branched into 2 parts from the first recovery flow path; and
a third recovery flow path connecting the second recovery flow path to the third supply flow path.

11. The apparatus of claim 10, wherein shapes of cross-sections of the second recovery flow path branched into 2 parts are identical to each other.

12. The apparatus of claim 11, wherein a sum of areas of cross-sections of the second recovery flow path branched into 2 parts is identical to an area of a cross-section of the first recovery flow path.

13. The apparatus of claim 10, wherein the first recovery flow path comprises:
a first first recovery flow path portion including a flexible material and connected to the storage portion; and
a second first recovery flow path portion including a solid material and connecting the first first recovery flow path portion to the second supply flow path.

14. The apparatus of claim 13, wherein the second first recovery flow path portion has a straight line shape.

15. The apparatus of claim 10, wherein each part of the second recovery flow path branched into 2 parts comprises:
a first second recovery flow path portion connected to the first recovery flow path and having a curved shape; and
a second second recovery flow path portion connecting the first second recovery flow path portion to the third recovery flow path and having a straight line shape.

16. The apparatus of claim 10, wherein the ink supply module further comprises a second pump arranged on the first recovery flow path in a way such that ink introduced into the recovery flow path flows into the storage portion.

17. The apparatus of claim 2, wherein the second flow path comprises:
a first second flow path connected to the storage portion;
a second second flow path branched into 2 parts from the first second flow path; and
a third second flow path connecting the second second flow path to the plurality of head portions.

18. The apparatus of claim 17, wherein shapes of cross-sections of the second second flow path branched into 2 parts are identical to each other.

19. The apparatus of claim 18, wherein a sum of area of cross-sections of the second second flow path branched into 2 parts is identical to an area of a cross-section of the first second flow path.

20. The apparatus of claim 19, wherein the first second flow path comprises:
a first sub supply flow path portion including a flexible material and connected to the storage portion; and
a second sub supply flow path portion including a solid material and connecting the first sub flow path portion to the second second flow path.
